(19) United States
(12) Patent Application Publication
(10) Pub. No.: US 2010/0050938 A1
(43) Pub. Date: Mar. 4, 2010

(54) Plasma processing apparatus

(75) Inventors: Tsutomu Tetsuka, Kasumigaura-shi (JP); Muneo Furuse, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi High-Technologies Corporation

(21) Appl. No.: 12/285,169

(22) Filed: Sep. 30, 2008

(30) Foreign Application Priority Data
Aug. 26, 2008 (JP) 2008-216344

(51) Int. Cl. C23C 16/513

(52) U.S. Cl. 118/697

(57) ABSTRACT

A plasma processing apparatus includes a sheet-like electrode for receiving high frequency signals from a plasma, a signal line connected to the electrode, a signal outputter which outputs high frequency signals from the electrode to the exterior, and a controller including of a physical quantity detecting unit, a measurement data storage unit, a measurement processing unit, and a control unit for controlling the apparatus parameters in response to signals from the measurement processing unit and performing control so as to stabilize the plasma condition. The signal line of the sheet-like electrode is formed between at least two layers of dielectric protection film formed on the surface of inner wall/inner cylinder 5 of a vacuum processing chamber in contact with plasma. The sheet-like electrode outputs an electric field/magnetic field.

The present application is based on and claims priority of Japanese patent application No. 2008-216344 filed on Aug. 26, 2008, the entire contents of which are hereby incorporated by reference.

### BACKGROUND OF THE INVENTION

1. Field of the Invention

The present invention relates to a plasma processing apparatus including a detecting means for detecting the plasma condition of the plasma processing apparatus and a detecting method thereof, and more specifically, relates to a plasma processing apparatus having a detecting means for detecting the plasma condition in detail without causing heavy metal contamination, so as to stably control the plasma condition.

2. Description of the Related Art

Recently, processing apparatuses using plasma have been applied widely in the processes of manufacturing not only semiconductor devices but also other products such as flat displays. In plasma processing apparatuses, reactive gases or deposition film material gases are discharged via microwaves or high frequency waves, depending on the aim of the process through which samples are processed. At this time, high energy electrons, ions and active radicals excited by the discharge cause the inner walls and the components of the vacuum processing chamber to be chipped via sputtering or chemically consumed, causing various drawbacks such as mixing of particles to the sample to be processed and heavy metal contamination of the wall surface material. Especially, as the semiconductor devices become highly integrated and the transistor structure becomes minute, the distance between circuit wiring becomes even smaller than 0.1 μm, so that even very minute particles may cause short circuit and other problems. Further, even if a small amount of heavy metal is mixed to the transistor circuit, the electric property thereof is varied and the yield of the products is deteriorated. According to such circumstances, the recent plasma processing apparatuses have a large portion of the surface of the inner wall of the vacuum processing chamber covered with chemically stable material or covered with quartz components. Further, in order to prevent generation of particles by reaction products formed during processing, stepped structures and observation ports on the inner wall of the vacuum processing chamber to which reaction products are easily attached and deposited are reduced.

On the other hand, along with the miniaturization of the semiconductor devices, the manufacturing processes thereof have become more complex and requires higher accuracy, so that there are increasing needs to constantly monitor the status of plasma processing and to control the same to determined values. The various parameters regarding plasma processing include discharge power and processing gas pressure that can easily be monitored and controlled as control parameters of the processing apparatus, but in general, it is difficult to monitor the change of distribution of plasma temperature or plasma density that directly influence the status of processing. A Langmuir measurement method in which a probe of a needle-like electrode is inserted to the plasma is known as the method for measuring the electron temperature and density of plasma, but in the plasma processing apparatuses used for manufacturing semiconductor devices, heavy metal contamination caused by the probe electrode will affect the performance of the semiconductor device, and the variation of processing properties caused by inserting a probe to the plasma causes deterioration of product yield.

Therefore, the plasma processing apparatuses used for manufacturing semiconductor devices widely adopt a method for observing the emission of plasma through an observation window formed on the side wall of the plasma processing apparatus as a means for monitoring the processing condition, as disclosed in the prior art example of Japanese patent application laid-open publication No. 05-259250 (patent document 1). Upon monitoring the plasma emission, it is necessary to form a dielectric window made for example of quartz with an inner diameter of approximately 10 mm on the wall surface of the plasma processing chamber at a position where plasma can be observed, and it is possible to adopt an arrangement in which metal components are not exposed to plasma, so that no heavy metal contamination is caused, and by placing the observation window away from the plasma, it becomes possible to suppress the influence that the window has on the processing conditions. The observed plasma emission data is used for controlling the process by extracting the signals reflecting the change of radical composition within the plasma or the variation of plasma condition based on the emission spectrum of various radicals.

According to the prior art disclosed in Japanese patent application laid-open publication No. 06-188220 (patent document 2) providing a temperature sensor on the inner wall of the plasma processing chamber to control the inner wall of the plasma processing chamber to a constant temperature so as to maintain a constant amount of reaction products caused by etching to be attached to the inner wall of the plasma processing chamber so as to improve the reproducibility of processing. A temperature sensor is relatively easily disposed, such as by forming a small hole from the atmospheric-pressure side of the inner wall made of metal of the processing chamber and inserting and attaching a small thermocouple thereto. Further, since the arrangement does not have any influence on the inner side of the plasma processing chamber, there are no concerns of the arrangement affecting the plasma or causing heavy metal contamination.

Japanese patent application laid-open publication No. 08-222396 (patent document 3) discloses a prior art of measuring a portion of the radio frequency discharge current via a measurement electrode serving as an earth electrode which is positioned in a flange or a recessed portion on a side wall of a reactor in an asymmetric radio-frequency low pressure plasma, wherein the measured signals are converted into digital signals to evaluate the plasma parameter via a mathematical algorithm.

However, according to the prior art plasma processing apparatuses, it is necessary to provide flanges having sensors for detecting the discharge current at positions coming in contact with plasma to measure the plasma condition, or provide observation windows at positions capable of directly observing the emission of plasma. In order to perform highly accurate plasma processing, it is preferable to increase the number of measurement points so as to measure the plasma condition in detail in order to control the processing apparatus with high accuracy, but it is difficult to provide multiple observations ports or flanges having a size of a few centimeters on the side wall of the vacuum processing chamber having a height of approximately 10 to 20 cm, and particles may be increased by providing projected or recessed structures on the inner wall of the vacuum processing chamber. Further, if a sensor is to be arranged within the conductor wall of the vacuum processing chamber, the physical quantity capable of being measured is restricted to the temperature or the like of the wall.

### SUMMARY OF THE INVENTION

The present invention aims at solving the problems of the prior art by providing a plasma processing apparatus capable of controlling plasma with high accuracy without providing disturbance to the plasma condition, without causing increase of particles, and without damaging the means for detecting the plasma condition.

The first aspect of the present invention provides a plasma processing apparatus including a vacuum processing chamber, a plasma generating means having a plasma-generating high frequency power supply and a magnetic coil to generate plasma in the vacuum processing chamber so as to subject a sample disposed in the vacuum processing chamber to plasma processing, the apparatus comprising: a sheet-like electrode disposed in the interior of the vacuum processing chamber for receiving a high frequency signal from an electric field or a magnetic field indicating the condition of plasma; a signal line connected to the sheet electrode; a signal output means for outputting the signal from the sheet-like electrode to the exterior of the vacuum processing chamber; and a control means comprising a physical quantity detecting unit for detecting a target physical quantity from the high frequency signal from the electric field or the magnetic field indicating the condition of plasma of the vacuum processing chamber, a measurement data storage unit for storing a past measurement data, a standard value and a new measurement data, a measurement processing unit for comparing the past measurement data and the standard value stored in the measurement data storage unit and the new measurement data detected by the physical quantity detecting unit so as to output a signal corresponding to the positional variation or overall density variation of plasma and to output a warning signal when the variation exceeds the standard value, and a control unit for controlling apparatus parameters such as the output of the plasma-generating high frequency power supply and the coil currents of the magnetic coils in response to the variation signal, the positional variation or the overall density variation of plasma from the measurement processing unit so as to stabilize the plasma condition; wherein the sheet-like electrode and the signal line are formed between at least two or more layers of dielectric protection film formed on a surface of an inner wall of the vacuum processing chamber in contact with plasma or on a surface of an inner cylinder having a metal base material arranged between the inner wall of the vacuum processing chamber and the plasma; and wherein the sheet-like electrode either receives or detects the electric field or the magnetic field from the plasma.

Further according to the plasma processing apparatus of the first aspect of the invention, the dielectric protection film is formed via a spray film of dielectric such as an oxide of aluminum or yttrium.

Moreover, according to the plasma processing apparatus of the first aspect of the invention, the sheet-like electrode is arranged on a surface of a dielectric film having a thickness of 10 to 300 μm formed on a surface of the inner wall of the vacuum processing chamber or on a surface of a base material conductor of an inner cylinder arranged within the vacuum processing chamber, and further having a dielectric sprayed film formed on the surface of the sheet-like electrode to a thickness of 10 to 300 μm.

According further to the plasma processing apparatus of the first aspect of the invention, the sheet-like electrode is a planar conductor capacitively coupled with plasma to detect the electric field, a spiral-shaped conductor having one end grounded for detecting the magnetic field, or an antenna for transmitting and receiving electromagnetic waves.

According further to the plasma processing apparatus of the first aspect of the invention, sheet-like electrodes are disposed at least at two locations on the inner wall coming in contact with plasma, high frequency current or voltage flowing in through the plasma to the inner wall of the vacuum processing chamber from the biasing high frequency power applied to the sample are detected at multiple varying locations, and the control means performs control so as to stabilize the condition of plasma based on the information regarding variation of plasma distribution from signals detected by the plurality of sheet-like electrodes.

Further according to the plasma processing apparatus of the first aspect of the invention, the signal output means comprises an output unit connected to the signal line and exposed to an exterior of the dielectric protection film, and an output signal line connected to a vacuum introduction terminal attached to a vacuum wall of the vacuum processing chamber via a connector, so as to output the detection signal detected by the sensing electrode to the exterior of the vacuum processing chamber.

According further to the plasma processing apparatus of the first aspect of the invention, the signal output means is composed of a first antenna such as a coil antenna or a dipole antenna connected to the signal line, and a second antenna such as a coil antenna or a dipole antenna connected to a vacuum introduction terminal attached to a vacuum wall of the vacuum processing chamber for receiving signals from the first antenna; and the sheet-like electrode and the physical quantity detecting means are connected to output the detection signal to the exterior of the vacuum processing chamber.

According further to the plasma processing apparatus of the first aspect of the invention, an IC chip connected to the sheet-like electrode and an antenna for outputting the detection signal to an external circuit are formed within the dielectric protection film at a location where it does not come in contact with high-density plasma, and management data stored in the IC chip such as individual identification information and operation time of components are output to the exterior of the vacuum processing chamber via the antenna, and stored in the measurement data storage unit.

According further to the plasma processing apparatus of the first aspect of the invention, the plasma processing apparatus includes a vacuum processing chamber, and a plasma generating means having a plasma-generating high frequency power supply and a magnetic coil to generate plasma in the vacuum processing chamber by introducing processing gas so as to subject a sample disposed in the vacuum processing chamber to plasma processing, wherein an electric circuit disposed in the interior of the vacuum processing chamber is covered with a dielectric protection film disposed on a surface of an inner wall of the vacuum processing chamber coming in contact with the plasma or on a surface of an inner cylinder formed of a metal base material disposed between the inner wall of the vacuum processing chamber and the plasma so that the electric circuit is not directly exposed to plasma, further comprising a first electrode disposed in the interior of the vacuum processing chamber and connected to the electric circuit for outputting signals from the electric circuit to an exterior of the vacuum processing chamber and a second electrode connected to a control means for controlling plasma generating conditions disposed in the exterior of the vacuum processing chamber, wherein the first electrode and the second electrode transmit and receive the signals via capacitive coupling or inductive coupling.

### BRIEF DESCRIPTION OF THE DRAWINGS

FIG. 1 is a cross-sectional view illustrating the outline of an arrangement of a plasma processing apparatus according to a first embodiment of the present invention;

FIG. 2 is a cross-sectional view illustrating an example of a sensing electrode according to the present invention;

FIG. 3 is a plan view illustrating an example of a sensing electrode according to the present invention;

FIG. 4 is a cross-sectional view illustrating an example of an arrangement of a signal output unit according to the present invention;

FIG. 5A is a plan view illustrating an example of the shape of a spiral sensing electrode according to the present invention, and FIG. 5B is an a-a cross-section thereof; and

FIG. 6 is a view illustrating an example of the measurement result according to the present invention.

### DETAILED DESCRIPTION OF THE PREFERRED EMBODIMENTS

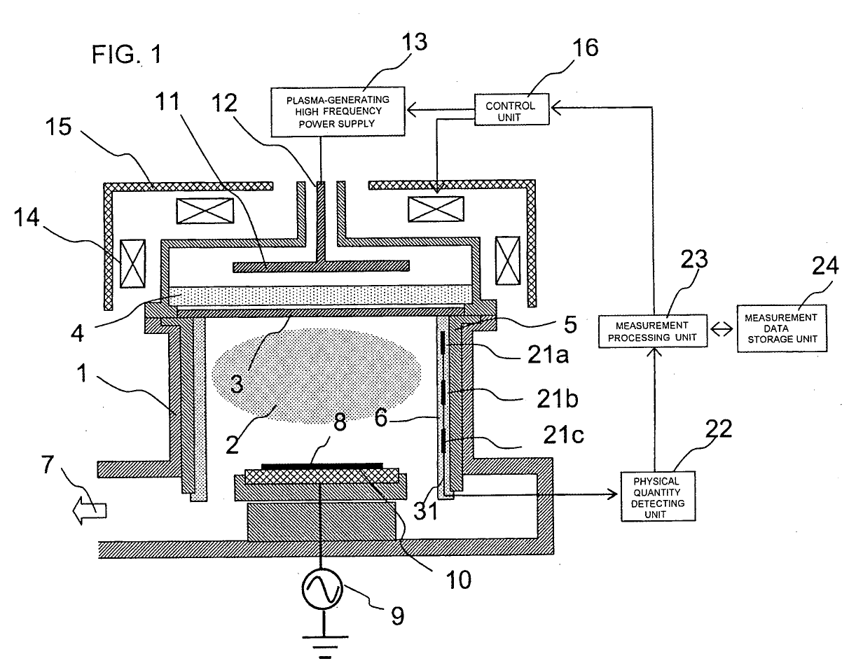

Now, the preferred embodiments for carrying out the present invention will be described with reference to FIGS. 1 through 6.

### Embodiment 1

FIG. 1 is referred to in illustrating a plasma processing apparatus according to the first embodiment of the present invention. The plasma processing apparatus is illustrated taking as an example a parallel plate plasma processing apparatus using microwaves or high frequency waves.

In FIG. 1, the plasma processing apparatus according to the present invention comprises a vacuum processing chamber 1, a gas discharge panel 3, a vacuum window 4, an inner cylinder 5, a dielectric protection film 6, an evacuation means 7, a biasing high frequency power supply 9, an electrostatic chuck (sample electrode) 10, a high frequency electrode 11, a coaxial pipe 12, a plasma generating high frequency power supply 13, a magnetic field coil 14, a yoke 15, a control unit 16, a plurality of sensing electrodes 21, a physical quantity detecting unit 22, a measurement processing unit 23, and a measurement data storage unit 24. The physical quantity detecting unit 22, the measurement processing unit 23, the measurement data storage unit 24 and the control unit 16 constitute a control means.

The vacuum processing chamber 1 for generating plasma and processing samples to be processed has surrounding walls formed of base material such as aluminum and stainless steel, and is connected to an evacuation means 7 for evacuating the vacuum processing chamber 1. A wafer 8, which is the sample to be processed, is held via electrostatic force by an electrostatic chuck 10 at the lower area of the vacuum processing chamber 1. A biasing high frequency power supply 9 is connected to the wafer 8 for applying high frequency to the wafer 8 so as to accelerate ions and promote irradiation. The details of the feeder connected to the electrostatic chuck 10 and the biasing high frequency power supply 9 or the cooling mechanism of the wafer 8 are not shown in the drawing, but the supporting unit of the wafer 8 is formed of many components.

A vacuum window 4 formed of dielectric material for introducing plasma-generating high frequency waves and a gas discharge panel 3 also formed of dielectric material are provided at the upper portion of the vacuum processing chamber 1. The plasma-generating high frequency waves are output from the plasma-generating high frequency power supply 13 with a frequency of tens of MHz to approximately 500 MHz, and via the coaxial pipe 12, are irradiated toward the inner side of the vacuum processing chamber 1 from the high frequency electrode 11. The high frequency electrode 11 is a metal disk-shaped member fixed via an insulating supporting member to a metal casing using screws or the like. Magnetic field coils 14 and a yoke 15 are arranged so as to surround the metal casing including the high frequency electrode 11 at the upper portion of the vacuum processing chamber 1, and by controlling the coil current of each of the magnetic field coils 14, a magnetic field is applied to the whole area of the vacuum processing chamber 1.

Plasma 2 is generated by ionizing the processing gas supplied through the gas discharge panel 3 using the mutual action of the high frequency electric field from the high frequency electrode 11 and the magnetic field. The generated plasma 2 has high temperature and high density near the high frequency electrode 11 having a strong high frequency electric field and in a magnetic field region where the high frequency electric field and magnetic field resonate, which may lead to damage of the inner walls of the vacuum processing chamber 1. Therefore, a dielectric protection film 6 formed of a substance having resistance to plasma and reactive radicals is formed on the inner wall of the vacuum processing chamber 1. Possible materials of the dielectric protection film 6 include a dielectric protection film formed by subjecting the surface of an aluminum base metal to a lumite processing, oxides of aluminum and yttrium, and polymer materials. Further, if reaction products generated during processing are attached and gradually deposited on the inner wall of the vacuum processing chamber 1, deposits detached therefrom become particles, possibly causing defective products.

Therefore, the inner wall of the vacuum processing chamber 1 must be cleaned periodically, so an inner cylinder 5 that can easy be removed and cleaned is disposed inside the vacuum processing chamber 1. Thus, the dielectric protection film 6 on the surface of the inner cylinder 5 exposed to the plasma 2 must have the highest strength, formed for example by thermally spraying yttria Y₂O₃ to a thickness of 0.1 mm to 0.5 mm on the surface of the aluminum base material.

A plurality of sensing electrodes 21a, 21b and 21c are formed on the inner side of the dielectric protection film 6 for measuring plasma 2. The positions and shapes of the sensing electrodes 21a, 21b and 21c are varied depending on the object of measurement, but the embodiment of FIG. 1 illustrates an example in which the sensing electrodes detect high frequency signals from the biasing high frequency power supply 9 applied to the wafer 8 so as to detect the variation of plasma 2 and control the same.

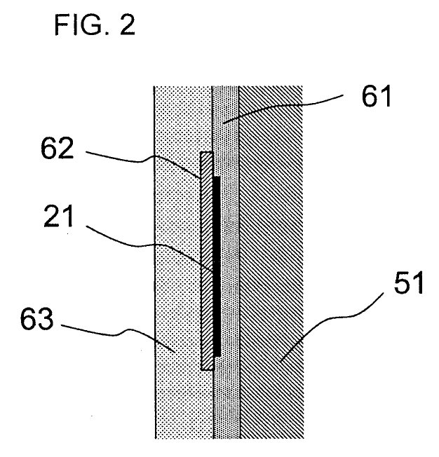

The basic structure of a sensing electrode is illustrated with reference to the cross-section of FIG. 2. In order to form a sensing electrode 21, at first, a base protection film 61 is formed by thermally spraying a dielectric film on the surface of an aluminum which is the inner base material 51 to a thickness of approximately 0.1 mm to 0.2 mm. The sensing electrode 21 has a thickness of approximately 50 μm to 100 μm, which is adhered to where the surface of the base protection film 61 is chipiped to a depth substantially corresponding to the thickness of the sensing electrode 21. When the protection film 63 is formed via a sprayed film, the sensing electrode 21 is covered with a sheet-like dielectric 62 such as ceramic, so that the sensing electrode 21 is not damaged by the heat during the thermal spraying, and a dielectric protection film 63 is deposited to a thickness of approximately 0.1 mm to 0.2 mm. The material of the sensing electrode 21 should preferably cause no metal contamination of the sample to be processed, and with respect to semiconductor devices, materials such as aluminum, yttria and tungsten can be used.

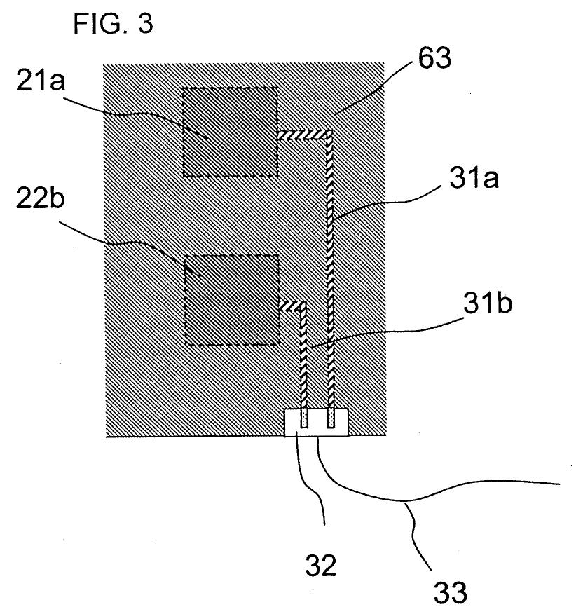

The configuration of a sensing electrode seen from plasma 2 will be described with reference to FIG. 3. The sensing electrode 21 of FIG. 3 detects high frequency signals from the plasma by being capacitively coupled with the plasma 2 and functioning equivalently as a capacitor. Therefore, the shape and size of the sensing electrode 21 is arbitrarily determined, and the shape is determined by the required detection sensitivity and space resolution. The high frequency signals detected by the sensing electrode 21 is transmitted via a signal line 31 to an output unit 32 of the high frequency signals. The first signal line 31 is formed within the dielectric protection film 63 with a similar arrangement as the detection electrode 21, and at the output portion 32 not covered by the dielectric protection film 63, it is connected via a connector or the like with a second signal line 33 connected to the exterior of the vacuum processing chamber.

The detected high frequency signals are transmitted to the exterior of the vacuum processing chamber from the second signal line 33 of FIG. 3 via a vacuum introduction terminal or the like disposed on the vacuum processing chamber. At this time, in reactive gas atmosphere, the output unit 32 of the first signal line 31 or the conductor portion of the second signal line 33 may be corroded by reactive gas, which may lead to deteriorated conduction.

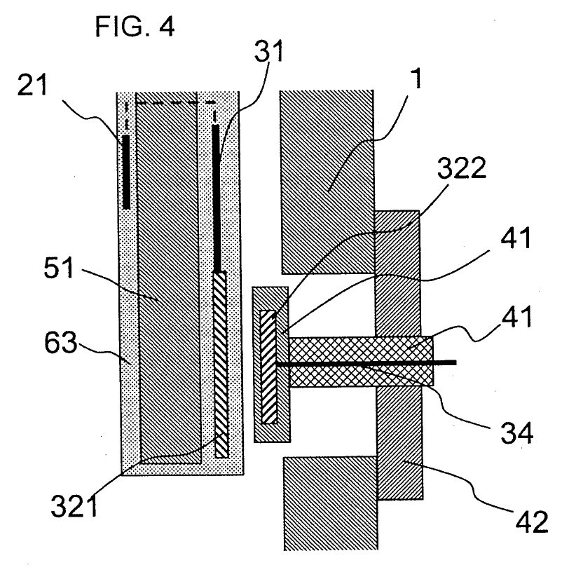

Another embodiment for taking out the detected signals to the exterior of the vacuum processing chamber will be described with reference to FIG. 4. A first signal line 31 and a signal antenna (first antenna) 321 are formed within the dielectric protection film 63 deposited on the surface of the inner base material 51 in the same manner as the sensing electrodes. High frequency signals detected via a sensing electrode not shown are transmitted through the first signal line 31. The first signal antenna 321 is electrically connected to a signal antenna (second antenna) 322 positioned facing the first signal antenna and drawn out to the exterior, wherein the first signal antenna 321 and the second signal antenna 322 communicate electromagnetic waves for example via capacitive coupling through a parallel plate arrangement, inductive coupling through an induction coil arrangement, or dipole antenna arrangement. The second signal antenna 322 and the external signal line 34 are respectively covered via a dielectric cover 41 or the like, and is fixed to a flange 42 disposed airtightly on the outer wall of the vacuum processing chamber 1. The second signal antenna 322 and the external signal line 34 can transmit high frequency signals to the exterior of the vacuum processing chamber 1 without having the conductor come in direct contact with reactive gas atmosphere.

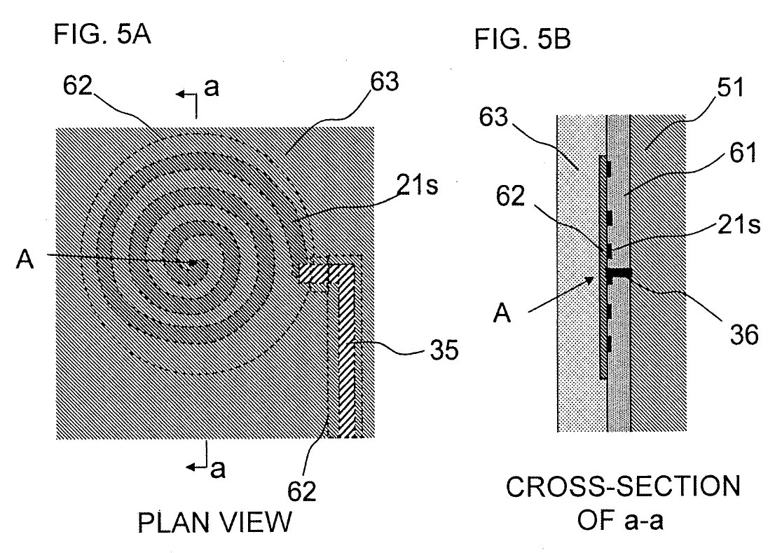

Another embodiment of a sensing electrode will be described with reference to FIG. 5. A spiral sensing electrode 21s of FIG. 5 detects the magnetic field variation of plasma through inductive coupling. One end of the spiral sensing electrode 21s formed in the shape of a coil or spiral is grounded via a conductor 36 to the inner base material 51 at a center position A, and the other end of the spiral sensing electrode 21s is connected to a signal line 35. The method for manufacturing the spiral sensing electrode 21 is similar to that of the sensing electrode 21 of FIG. 2. The surface of the spiral sensing electrode 21s and the signal line 35 are respectively covered by a sheet-like dielectric 62.

The high frequency signals detected by the spiral sensing electrode 21s of FIG. 5 is transmitted to the exterior of the dielectric protection film 6 from the lower end of the inner cylinder 5 distanced from the center portion of the plasma 2, and conducted to the exterior of the vacuum processing chamber 1 via a vacuum introduction terminal not shown. In the embodiment of FIG. 5, the high frequency waves applied to the wafer 8 are propagated through the plasma 2 and detected by the capacitive coupling of the plasma 2 and the spiral sensing electrode 21s. The detected high frequency signals are transmitted via a signal transmission means as illustrated in FIGS. 3 and 4, for example, to a physical quantity detecting means 22 at the exterior of the vacuum processing chamber. The physical quantity sensing means 22 detects the target physical quantity based on the high frequency signals detected by the spiral sensing electrode 21s. The physical quantity can be obtained for example by detecting the voltage of the high frequency signals of the spiral sensing electrode 21s directly via an oscilloscope, grounding the output of the spiral sensing electrode 21s with a low impedance and detecting the high frequency current flowing through the output line via a current probe, or detecting high frequency power. Further, it is also possible to perform active measurement by irradiating electromagnetic waves from the first spiral sensing electrode 21s and sensing the reflected waves from the plasma by a second spiral sensing electrode 21s to measure the plasma density.

According to the embodiment of FIG. 1, the variation of plasma is detected through high frequency signals measured via sensing electrodes 21a, 21b and 21c disposed at three locations, and based on the detected plasma variation information, the plasma processing apparatus is controlled in order to stabilize the processing condition. The high frequency signal outputs measured via the respective sensing electrodes 21 are each grounded via a low resistance line at each measurement unit 21, and the high frequency currents flowing through the low resistance lines are detected for example via a current probe. The newly detected current value data (measurement data) of the sensing electrodes 21a, 21b and 21c are compared in a measurement processing unit 23 with past measurement data and standard values stored in a measurement data storage unit 24, and if the plasma variation quantity signal or the plasma variation quantity exceeds a defined value, a warning signal is transmitted to a control unit 16 of the plasma processing apparatus. In the control unit 16, the output of the plasma generating high frequency power supply 13 or the apparatus parameters of the coil currents or the like of the magnetic field coils 14 are controlled in response to the positional change of plasma or the overall density change of plasma, in order to stabilize the plasma condition.

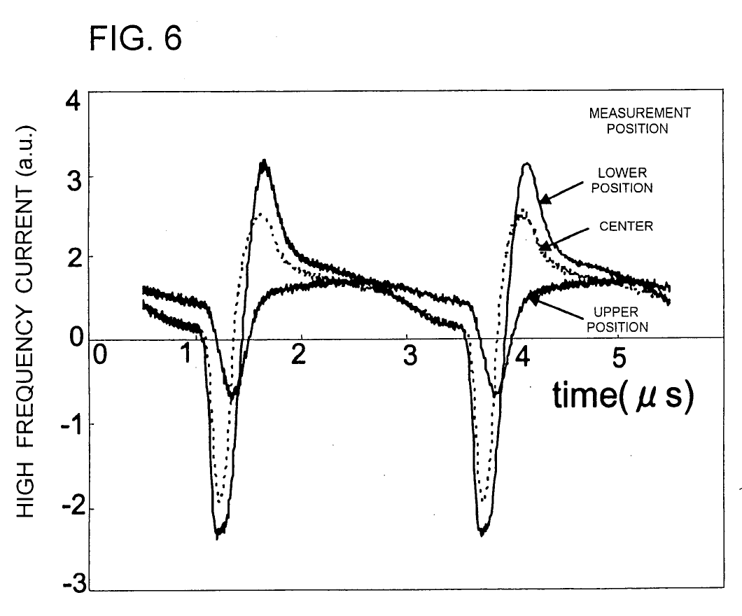

A measurement example of the high frequency current measured via the sensing electrodes 21 is illustrated in FIG. 6. In the measurement of FIG. 6, sensing electrodes formed of aluminum sheets (each having a thickness of 50 μm, a width of 50 mm and a height of 20 mm) were arranged at three locations in a height direction (upper portion, center portion and lower portion) on the side wall of the vacuum processing chamber 1, and a simple dielectric sheet made of resin was applied as protection film for the sensing electrodes to perform measurement. The frequency of the high frequency applied to the wafer 8 was 400 kHz. As for the signals detected through each of the sensing electrodes, high frequency currents were detected via a current probe and the waveforms were observed via a oscilloscope. The discharge gas was chlorine and the pressure was 0.4 Pa. As can be recognized from FIG. 6, the waveforms were clearly different depending on the measurement positions. The details of the high frequency current waveform were changed depending on discharge conditions such as gas species, pressure and discharge power. The high frequency current waveforms are considered to reflect the plasma density distribution, the electron temperature and the magnetic field coordination, and for example, if the plasma shifts to the upper or lower direction, such shift is considered to be distinguished by the change in high frequency current waveform as shown in FIG. 6. Therefore, if the shift of plasma in the upper or lower direction can be detected, it becomes possible to control the current of magnetic field coils 14 via the control unit 16 of FIG. 1 so as to change the magnetic field coordination and correct the plasma distribution.

Next, we will describe an embodiment in which an IC chip disposed within the vacuum processing chamber is used to manage the identification information of components and the operating time thereof. According to the present embodiment, an IC chip connected to a sheet-like electrode and an antenna for outputting the detection signals to an external circuit are disposed within a dielectric protection film at a position where it is not exposed to high-density plasma within the vacuum processing chamber. The IC chip stores management data including the individual identification information of components such as the surrounding wall of the vacuum processing chamber 1 or the inner cylinder 5 and the operating time thereof. The plasma processing apparatus transmits the management data via an antenna to the exterior, which can be read in a noncontact manner, and the conditions of the components can be managed by storing the management data in the measurement data storage unit, so that it becomes possible to clean the inner wall or the inner cylinder of the vacuum processing chamber at appropriate timings.

According to the plasma processing apparatus of the above-mentioned embodiments, sensing electrodes are arranged within the layers of the dielectric protection film, so that it becomes possible to provide a plurality of sensing electrodes or a large-sized sensing electrode for sensing the plasma status on the inner wall of the vacuum processing chamber without causing heavy metal contamination of the sample being processed. Further, since the sensing electrodes and signal lines are formed within the dielectric protection film, they will not be damaged by plasma or deteriorated by corrosion due to reactive gas, and stable measurement can be performed for a long period of time. Further, by arranging a plurality of sensing electrodes at arbitrary positions on the inner wall of the vacuum processing chamber, the plasma position or density changes can be measured with higher accurately. As a result, the plasma processing apparatus can be controlled via correct measurement data, so that highly accurate and stable plasma processing is enabled.

The present invention is especially useful in detecting and monitoring the status of a plasma processing apparatus especially applied to manufacturing semiconductors, enabling stable processing to be performed for a long period of time.

What is claimed is:

1. A plasma processing apparatus including a vacuum processing chamber, a plasma generating means having a plasma-generating high frequency power supply and a magnetic coil to generate plasma in the vacuum processing chamber, to generate plasma in the vacuum processing chamber to subject a sample disposed in the vacuum processing chamber to plasma processing, the apparatus comprising:
a sheet-like electrode disposed in the interior of the vacuum processing chamber for receiving a high frequency signal from an electric field or a magnetic field indicating the condition of plasma;
a signal line connected to the sheet electrode;
a signal output means for outputting the signal from the sheet-like electrode to the exterior of the vacuum processing chamber; and
a control means comprising a physical quantity detecting unit for detecting a target physical quantity from the high frequency signal from the electric field or the magnetic field indicating the condition of plasma of the vacuum processing chamber, a measurement data storage unit for storing a past measurement data, a standard value and a new measurement data, a measurement processing unit for comparing the past measurement data and the standard value stored in the measurement data storage unit and the new measurement data detected by the physical quantity detecting unit so as to output a signal corresponding to the positional variation or overall density variation of plasma and to output a warning signal when the variation exceeds the standard value, and a control unit for controlling apparatus parameters such as the output of the plasma-generating high frequency power supply and the coil currents of the magnetic coils in response to the variation signal, the positional variation or the overall density variation of plasma from the measurement processing unit so as to stabilize the plasma condition; wherein
the sheet-like electrode and the signal line are formed between at least two or more layers of dielectric protection film formed on a surface of an inner wall of the vacuum processing chamber in contact with plasma or on a surface of an inner cylinder having a metal base material arranged between the inner wall of the vacuum processing chamber and plasma; and wherein the sheet-like electrode either receives or detects the electric field or the magnetic field from the plasma.

2. The plasma processing apparatus according to claim 1, wherein
the dielectric protection film is formed via a spray film of dielectric such as an oxide of aluminum or yttrium.

3. The plasma processing apparatus according to claim 1, wherein
the sheet-like electrode is arranged on a surface of a dielectric film having a thickness of 10 to 300 μm formed on a surface of the inner wall of the vacuum processing chamber or on a surface of a base material conductor of an inner cylinder arranged within the vacuum processing chamber, and further having a dielectric sprayed film formed on the surface of the sheet-like electrode to a thickness of 10 to 300 μm.

4. The plasma processing apparatus according to claim 1, wherein
the sheet-like electrode is a planar conductor capacitively coupled with plasma to detect the electric field, a spiral-shaped conductor having one end grounded for detecting the magnetic field, or an antenna for transmitting and receiving electromagnetic waves.

5. The plasma processing apparatus according to claim 1, wherein
sheet-like electrodes are disposed at least at two locations on the inner wall of the vacuum processing chamber in contact with plasma;
high frequency current or voltage flowing in through the plasma to the inner wall of the vacuum processing chamber from the biasing high frequency power applied to the sample are detected at multiple varying locations; and
the control means performs control so as to stabilize the condition of plasma based on the information regarding variation of plasma distribution from signals detected through the plurality of sheet-like electrodes.

6. The plasma processing apparatus according to claim 1, wherein
the signal output means comprises an output unit connected to the signal line and exposed to an exterior of the dielectric protection film, and an output signal line connected to a vacuum introduction terminal attached to a vacuum wall of the vacuum processing chamber via a connector, so as to output the detection signal detected by the sensing electrode to the exterior of the vacuum processing chamber.

7. The plasma processing apparatus according to claim 1, wherein
the signal output means is composed of a first antenna such as a coil antenna or a dipole antenna connected to the signal line, and a second antenna such as a coil antenna or a dipole antenna connected to a vacuum introduction terminal attached to a vacuum wall of the vacuum processing chamber for receiving signals from the first antenna; and
the sheet-like electrode and the physical quantity detecting means are connected to output the detection signal to the exterior of the vacuum processing chamber.

8. The plasma processing apparatus according to claim 1, wherein
an IC chip connected to the sheet-like electrode and an antenna for outputting the detection signal to an external circuit are formed within the dielectric protection film at a location where it is not in contact with high-density plasma; and
management data stored in the IC chip such as individual identification information and operation time of components are output to the exterior of the vacuum processing chamber via the antenna and stored in the measurement data storage unit.
